(19) United States
(12) Patent Application Publication
(10) Pub. No.: US 2007/0166847 A1
(43) Pub. Date: Jul. 19, 2007

(54) Boxes for Soft Error Rate Calculation

(75) Inventor: David E. Fulkerson, Chanhassen, MN (US)

Correspondence Address: HONEYWELL INTERNATIONAL INC., 101 COLUMBIA ROAD, P O BOX 2245, MORRISTOWN, NJ, 07962-2245, US

(73) Assignee: Honeywell International Inc., Morristown, NJ (US)

(21) Appl. No.: 11/538,928

(22) Filed: Oct. 5, 2006

Related U.S. Application Data
(60) Provisional application No. 60/759,344, filed on Jan. 17, 2006.

(51) Int. Cl. H01L 21/66; G01R 31/26

(52) U.S. Cl. 438/17

(57) ABSTRACT

Memory and logic error rates are predicted by breaking each transistor into theoretical “boxes” with differing sensitivities to ionizing radiation. The box dimensions and critical charge are determined using physics-based equations. The box dimensions and critical charge are used to calculate soft error rate (SER). This box method may be used to calculate SER due to an ion that simultaneously strikes two separate sensitive volumes in order to cause an upset. Additionally, the box method may used to predict upsets that occur when an ion strike pulls a circuit node below ground or above the positive power supply.

### RELATED APPLICATIONS

The present patent application claims priority under 35 U.S.C. § 119(e) to U.S. Provisional Patent Application Ser. No. 60/759,344, which was filed Jan. 17, 2006. The full disclosure of U.S. Provisional Patent Application Ser. No. 60/759,344 is incorporated herein by reference.

### FIELD

The present invention relates generally to circuit modeling, and more particularly, to predicting soft error rate due to ion strikes within an integrated circuit cell.

### BACKGROUND

A Single Event Effect (SEE) is a disturbance in an active electronic device caused by a single, energetic particle. One type of SEE is a Single Event Upset (SEU). An SEU is a radiation-induced error in a semiconductor device caused when a charged particle loses energy by ionizing the medium through which it passes, leaving behind a wake of electron-hole pairs, forming a parasitic conduction path. The parasitic conduction path causes a false transition on a node. The false transition, or glitch, propagates through the semiconductor device and ultimately results in the disturbance of a node containing state information, such as an output of a latch or register.

Typically, an SEU is caused by ionizing radiation components in the atmosphere or in space, such as neutrons, protons, and heavy ions. Additionally, an SEU can be caused by alpha particles from the decay of trace concentrations of uranium and thorium present in some integrated circuit packaging. As another example, an SEU may be caused by a detonated nuclear weapon. When a nuclear weapon is detonated, intense fluxes of gamma rays, x-rays, and other high energy particles are created.

Some semiconductor devices are designed to operate in conditions that expose the devices to energetic particles. Thus, a simple method is needed to characterize the SEU behavior of Random Access Memory (RAM) cell types, latches, flip-flops, other logic cells, I/O cells, and so on. The CREME96 program has long been used to calculate soft error rate (SER) for radiation environments using a rectangular parallelepiped (RPP) representing the vulnerable “sensitive volume” of a circuit. This RPP can be characterized by a critical charge required to upset the cell in question. The CREME96 user must determine the dimensions of the RPP. The CREME96 SER calculation is very sensitive to these dimensions.

Previously, in U.S. patent application No. 11/200,414, which is assigned to the same assignee as the current application, a method was described that characterized each circuit transistor by several regions of differing critical charges. U.S. patent application No. 11/200,414 is hereby incorporated by reference in its entirety. While these regions allowed the prediction of the circuit response to vertical ion strikes, the response to ion strikes from all directions, as seen in typical space applications, remains problematic.

Thus, an improved method for predicting SER due to ion strikes within an integrated circuit cell would be beneficial.

### SUMMARY

A method for calculating SER due to ion strikes within an integrated circuit cell is described. In one example, the method for calculating a soft error rate includes identifying at least one transistor in an integrated circuit cell that if impacted by an ion strike can cause an erroneous output of the integrated circuit cell; identifying at least one portion of the at least one transistor that is sensitive to the ion strike; and determining a critical charge and a dimension for the at least one portion. The at least one portion may be represented by a box.

The at least one portion may be located in a region in which the ion strike causes parasitic bipolar action to occur. The critical charge may be determined by calculating an ion-induced drain current and using the calculation to simulate the critical charge. A circuit simulator, such as SPICE, may be used to simulate the critical charge. The dimension may be determined by defining an x-dimension of a first box to contain positions in which the critical charge ranges from a minimum critical charge to two times the minimum critical charge. The first box may be characterized as having a charge equal to an average of the minimum critical charge and two times the minimum critical charge.

Additional boxes may be determined by defining an x-dimension in which the critical charge ranges from a factor of two from the critical charge range of the first box. These additional boxes may be characterized as having a charge equal to an average of the critical charge range.

The at least one portion may be located in a region in which the ion strike causes a drain of the at least one transistor to become forward biased. The critical charge may be determined by calculating a forward biased drain current that accounts for diode action and using the calculation to simulate the critical charge. A circuit simulator, such as SPICE, may be used to simulate the critical charge. The dimension may be determined by defining an x-dimension of a box such that a value of the critical charge varies by a factor of two. The box may be characterized as having a charge of an average of the critical charge range of the box.

The critical charge and the dimension may be used to calculate a soft error rate for the integrated circuit cell. In one example, a partial soft error rate may be determined for each of the portions of each of the transistors and the partial soft error rates are added to calculate the soft error rate for the integrated circuit cell. In another example, a partial soft error rate is determined for a dominant portion of each of the transistors and the partial soft error rates are added to calculate the soft error rate for the integrated circuit cell.

In another example, the method includes calculating a soft error rate due to an ion that strikes two transistors to cause an upset. The method includes identifying two transistors in an integrated circuit cell that if both are impacted by an ion strike can cause an erroneous output of the integrated circuit cell; modeling the two transistors as two boxes each having a dimension; and calculating a soft error rate due to an ion striking the two boxes as a function of the box dimensions, distance from a center of the first box to the center of the second box, and an integral flux. One of the two transistors may be a redundant transistor used to harden the integrated circuit cell.

Calculating the soft error rate may include using the formula: SER=2 F(Lₒ)w₁d₁w₂d₂/r², where F(L) is the integral flux (in units of particles per μm²-steridian-day), Lₒ is the critical linear energy transfer (LET) required to cause an upset when both boxes are hit, r is the distance from the center of one box to the other, w is a width of the box, and d is a depth of the box. The method may also include transforming the two boxes if the boxes do not face each other.

In another example, the method includes calculating a soft error rate to predict upset when an ion strike pulls a circuit node below ground or above a positive power supply. The method includes identifying at least one transistor in an integrated circuit cell that if impacted by an ion strike on a body tie region can cause a circuit node to be pulled below ground or above a positive power supply; determining a critical charge for a portion of the transistor that includes at least part of a body and part of a drain of the transistor; determining an x-dimension for the portion that contains positions in which the critical charge ranges from a minimum critical charge to two times the minimum critical charge; characterizing the portion as having a charge equal to an average of the minimum critical charge and two times the minimum critical charge; and using the critical charge and the dimension to predict a total soft error rate for the integrated circuit cell.

These as well as other aspects and advantages will become apparent to those of ordinary skill in the art by reading the following detailed description, with reference where appropriate to the accompanying drawings. Further, it is understood that this summary is merely an example and is not intended to limit the scope of the invention as claimed.

### BRIEF DESCRIPTION OF THE DRAWINGS

Presently preferred embodiments are described below in conjunction with the appended drawing figures, wherein like reference numerals refer to like elements in the various figures, and wherein:

FIG. 1 shows a circuit diagram of a hardened SRAM cell;

FIG. 2 shows a typical layout of a transistor of the SRAM cell depicted in FIG. 1;

FIG. 3 shows the layout of FIG. 2 separated into seven boxes of differing dimensions and critical charge, according to an example;

FIG. 4 is a graph of theoretical and experimental cross-section vs. linear energy transfer (LET) curves for vertical ion strikes on the SRAM cell depicted in FIG. 1;

FIG. 5 is a pictorial representation of an ion strike through two separated boxes; and

FIG. 6 is a pictorial representation of an ion strike through two separated boxes that do not directly face each other.

### DETAILED DESCRIPTION

A method for predicting SER due to ion strikes within an integrated circuit cell is described. The method includes determining the critical charge and dimensions of a rectangular parallelepiped (RPP) or “box” for several regions of a critical transistor (i.e., a transistor that if hit by an ion strike may cause an erroneous output of the circuit that includes the transistor). Additionally, the method allows for calculation of SER due to an ion that simultaneously strikes two separated sensitive volumes in order to cause an upset. The method may also be used to predict unusual upset phenomena that can occur when an ion strike pulls a circuit node below ground or above the positive power supply.

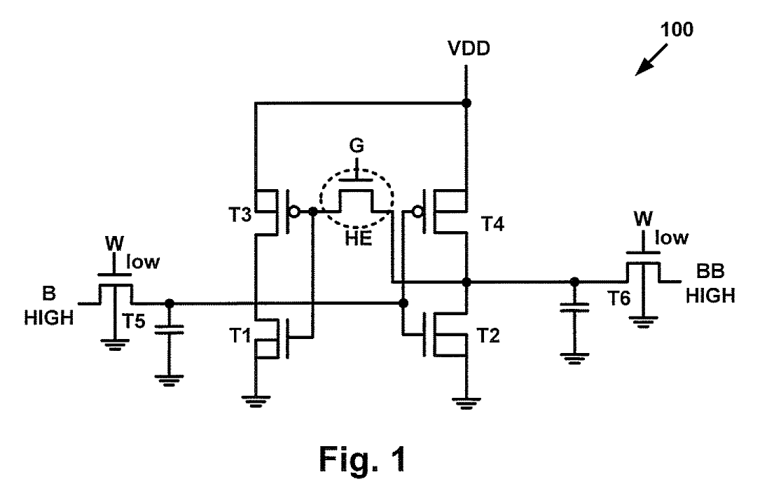

FIG. 1 shows the circuit diagram of a hardened Static Random Access Memory (SRAM) cell 100. The hardened SRAM cell 100 may include a hardening element, which is symbolically depicted in FIG. 1 as “HE”. The hardening element may be gated into a low impedance state for writing. If the hardening element is permanently gated on, the SRAM cell 100 may behave like a non-hardened six-transistor cell.

While the method described as follows uses the SRAM cell 100, it is understood that the method is applicable to a wide-variety of integrated components, such as other memory types, latches, flip-flops, logic cells, and I/O cells. Additionally, the fabrication process used in the following description is a radiation-hard 0.15 μm partially-depleted SOI process known as S150T. However, the invention is not limited to this process.

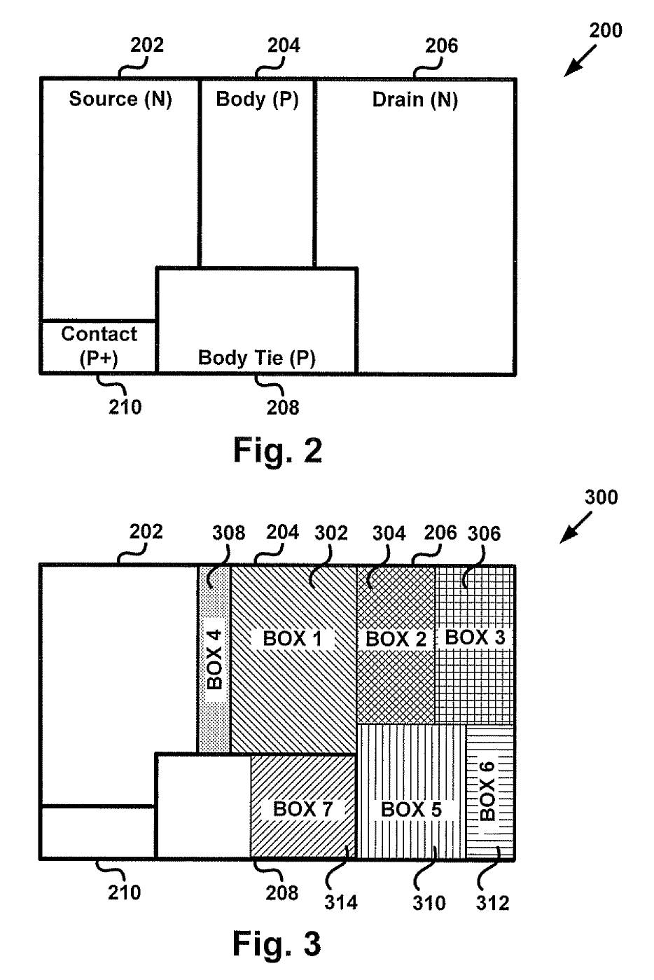

FIG. 2 shows a typical layout 200 of the NMOS pull-down transistor (T1) depicted in FIG. 1. The transistor layout 200 includes a source 202, a body 204, a drain 206, a body tie 208, and a contact 210. It is understood that the transistor layout 200 may vary based on design considerations, such as wafer space, operating speed, and avoiding SEE.

FIG. 3 shows the layout of FIG. 2 separated into seven boxes 302-314 of differing dimensions and critical charge. The boxes 302-314 are not located in a portion of the source 202 as two-dimensional simulations have shown that ion strikes on the source 202 have a minimal effect on SER.

An ion strike on boxes 302-308 may produce a charge cloud that collides with the drain junction at a point where parasitic bipolar action can occur. Depending on whether the strike is in an N-type or P-type material, the collector-to-base current is modeled as either I_{N}(xₛ,t) or I_{P}(xₛ,t), where xₛ is the distance from the strike location to the drain junction. According to one example, I_{N}(xₛ,t) may be calculated using a one-dimensional solution to the carrier transport equations, which shows that for an ion strike in N-type material, the resulting drain junction current may be:

$$\begin{matrix}{I}_{N} ( {x}_{s} , t ) = exp ( - t / τ ) \frac{2 {Q}_{d}}{π {t}_{N}} {\sum }_{m = 1 , 2 , 3 , 5} [ m sin ( m π / 4 ) exp ( - {m}^{2} t / {t}_{N} ) ] \\ where \text{:} & ( 1 ) \\ {t}_{N} = \frac{16 {x}_{s}^{2}}{{π}^{2} D} & ( 2 )\end{matrix}$$

and where Q_{d} is the deposited charge and D is the diffusion constant.

Similar equations can be derived for an ion strike in P-type material. The transport equations for P-type material may vary from the N-type material equations due to the electron cloud pull effect. For example, for high injection in P-type material, the transport equations may be:

$$\begin{matrix}{I}_{P} ( {x}_{s} , t ) = \frac{9 {Q}_{d}}{8 {t}_{P}} [ exp ( - t / {t}_{P} ) - exp ( - 9 t / {t}_{P} ) ] \\ where \text{:} & ( 3 ) \\ {t}_{P} = \frac{4 {x}_{s}^{2}}{{π}^{2} D} & ( 4 )\end{matrix}$$

and where Q_{d} is the deposited charge and D is the diffusion constant. Using Equation (3), the stored charge when the drain is reverse biased may be described as:

$$\begin{matrix}Q ( t ) = {Q}_{d} - {\int }_{0}^{t} {I}_{P} ( {x}_{s} , t ) ⅆ t \\ = ( {Q}_{d} / 8 ) [ 9 exp ( - t / {t}_{P} ) - exp ( - 9 t / {t}_{P} ) ] .\end{matrix} \qquad ( 5 )$$

While Equation (1) or (3) may be used to determine the ion-induced drain current in a transistor, it is understood that these equations may be modified based on the location of the ion strike. According to Equations (1) and (3), the drain current is a function of the distance from the ion strike to the drain junction. Using a simulation model (including the effects of the parasitic bipolar transistor), the critical charge Q_{c} necessary to upset the SRAM cell 100 can be simulated for any value of xₛ. SPICE (and its variations) is one of the most common circuit simulation programs; however, other simulation programs may be used, including a custom simulation program.

The x-dimensions of the first box 302 are defined to contain positions where Q_{c} varies from the minimum critical charge (Q_{c1min}) to two times the minimum critical charge (2Q_{c1min}). The first box 302 is then characterized by the average value of Q_{c} (1.5 Q_{c1min}). In this example, the first box 302 is comprised of most of the body 204 (under the gate) plus part of the drain 206.

Similarly, the x-dimensions of the second box 304 are defined for those strike locations where Q_{c} varies from 2Q_{c1min} to 4Q_{c1min}. The second box 304 is then characterized by the average value of 3Q_{c1min}. The third box 306 is similarly defined for those strike locations where Q_{c} varies from 4Q_{c1min} to 8Q_{c1min}, with the average value of 6Q_{c1min}. In this example, both the second box 304 and the third box 306 are located in the drain 206. The fourth box 308, which is located in the body 204, is also defined with its average Q_{c}.

An ion strike in boxes 310-314 may be modeled to account for diode action when the drain 206 becomes forward biased. For example, the stored charge when the drain is forward biased may be described as:

$$\begin{matrix}Q ( t ) = \frac{4 {Q}_{d}}{π} {\sum }_{m = 1 ( m odd )} [ 1 / m sin ( 3 m π / 8 ) exp ( - {m}^{2} t / {t}_{T} ) ] \\ where \text{:} & ( 6 ) \\ {t}_{N} = \frac{4 {w}^{2}}{{π}^{2} D} . & ( 7 )\end{matrix}$$

The box dimensions of the boxes 310-314 are chosen such that the value of Q_{c} for these boxes also varies by a factor of two, and the Q_{c} of each box is taken as the average of Q_{c}.

The boundary between the fifth box 310 and the second box 304 is chosen by attributing to the fifth box 310 those strikes that first collide with a passive part of the drain junction rather than the edge of a parasitic bipolar transistor. The boundary of the sixth box 312 is similarly determined. An ion strike in the seventh box 314 (in the body tie region 208) also produces drain current, but it is not amplified by the bipolar action because the resultant charge cloud first strikes the passive portion of the drain 206.

By choosing the box characteristics as described, the calculation of SER is simplified and allows SER for each box to be calculated independently (i.e., ignoring ion strikes that go through more than one box). Additionally, the boxes 302-314 can be defined for a particular transistor in a particular circuit. For example, in the SRAM cell 100, the PMOS pull-up transistor (T4) and the NMOS access transistor (T6) can be analyzed using boxes in the same way as described above with respect to the NMOS pull-down transistor (T1).

While seven boxes are used in the example depicted in FIG. 3, more or less than seven boxes may be used to model ion strikes on a transistor. For example, as described below, a single dominant box may be used to predict SER.

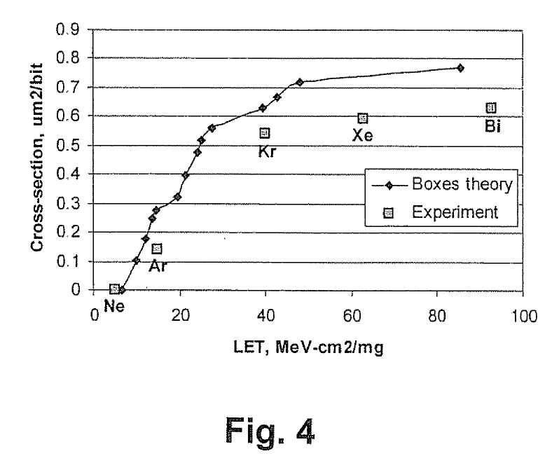

FIG. 4 is a graph of theoretical and experimental cross-section vs. linear energy transfer (LET) curves for vertical ion strikes on the T1, T4, and T6 transistors in the SRAM cell 100 depicted in FIG. 1. Each theoretical data point in FIG. 4 represents one box. The critical charge Q_{c} was converted to LET using the following equation:
LET=0.1Q_{c}/l (8)
where LET is in units of MeV-cm²/mg, Q_{c} is in fC, and l is the path length through the Si in μm (0.14 μm for a vertical strike in the body or drain regions, and 0.05 μm for the body region).

Also shown in FIG. 4 are experimental results. A six-transistor SRAM was tested for vertical heavy ion upset at the Berkeley Cyclotron. As seen in FIG. 4, there is agreement between theory and experimental results.

After determining the dimensions and critical charges of the boxes 302-314, the SER may be calculated using CREME96, which calculates SER on a single box. The total SER of the circuit may be the sum of the calculated SER of each box. Using the example depicted in FIG. 3 and assuming a radiation environment of a near-earth interplanetary/geosynchronous orbit with 100 mils of Al shielding, the total SER was found to be 5.E-9 error/bit-day (e/b-d). Additionally, the results showed that the first box 302 was the dominant box for each of the critical transistors T1, T4, and T6. As a result, each transistor may be adequately represented by a single box.

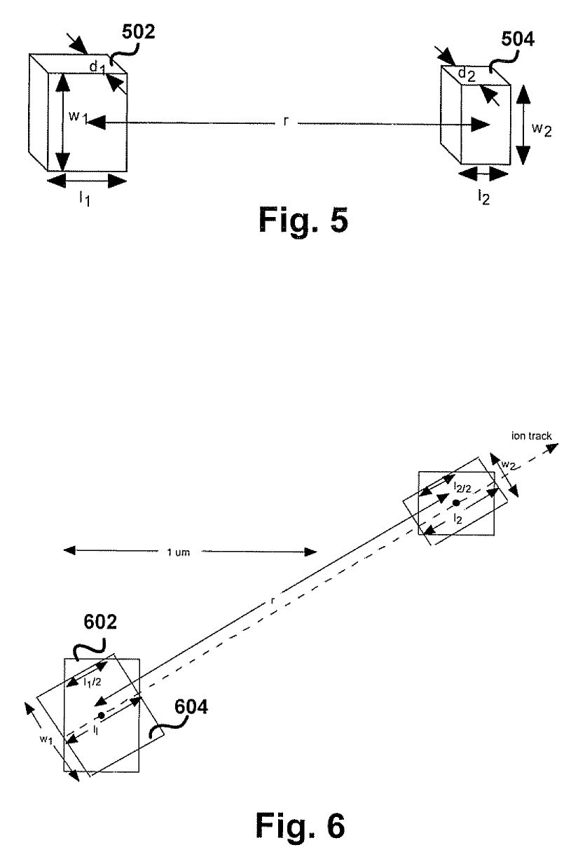

While the previous discussion was for the case in which an ion strike occurred on a single transistor, the box method may also be used to analyze an ion striking two transistors. Using the box method for analyzing an ion striking two transistors may be important especially to a hardened device, such as the SRAM cell 100, for which an upset may occur if an ion strikes two transistors. In this case, each transistor may be modeled with its own box as shown in FIG. 5.

FIG. 5 shows the configuration of two boxes 502, 504 representing two transistors. It can be shown that, for r comparable to or larger than the other dimensions in FIG. 5, the SER due to an ion striking the two boxes 502, 504 is:
SER=2F(Lₒ)w₁d₁w₂d₂/r² (9)
where F(L) is the integral flux (in units of particles per μm²-steridian-day), Lₒ is the critical LET required to cause an upset when both boxes are hit, r is the distance from the center of one box to the other, and the other dimensions are as shown in FIG. 5. Equation (9) may be used to analyze a wide variety of cells that have redundant transistors to increase radiation hardness.

Equation (9) is derived as follows. Consider a particle striking the left side of the box 502. F(L) is given in units of particles per μm²-steradian-day. The number of steradians that a particle track must subtend in order to also hit the box 504 is w₂d₂/r². This amount is then multiplied by the area of the box 502 being struck (i.e., w₁d₁) to obtain the total number of such critical particles. The above explanation describes a particle first striking the box 502. However, a failure may also occur if the particle first strikes the box 504. Repeating the analysis for this case adds a factor of two in Equation (9).

FIG. 6 shows the configuration for two boxes that do not face each other. SER may be calculated by transforming the original boxes 602 as shown in FIG. 6. The path lengths through the centers of the new boxes 604 are l₁ and l₂. The new widths w₁ and w₂ are chosen such that the path lengths through the edges of the new boxes are l₁/2 and l₂/2. The new r is again the center-to-center spacing. Equation (9) is then applied to the dimensions of the new boxes.

The SRAM cell 100 has another upset mechanism. If transistor T2 depicted in FIG. 1 is off and an ion strikes T2 in the body tie region 208 (the seventh box 314), the T2 drain pulls below ground until it is clamped by the body-to-drain diode. This can turn on the hardening element HE, which pulls the output low causing an upset. It might seem that the series resistance of the body tie region would mitigate this phenomenon, but the free carriers injected by the ion reduce this resistance. By using the box method described herein, the resultant SER is 1.E-16 errors per bit-day. A body tie strike on transistor T4 produces a similar SER. Although this SER is low, the result is only for one particular circuit. This phenomenon may be important for other cells that have series transistors to increase radiation hardness.

As described above, the method described herein allows for SER calculation in integrated circuits, taking account of ion trajectories from all directions. Using physics-based closed-form equations in SPICE (or other circuit) simulations, each transistor in a circuit can be separated into sensitive volumes (boxes) that takes into account ion strikes on the body 204, drain 206, and body-tie 208 regions. For example, in the SRAM cell 100, the NMOS inverter pull-down transistor T1, PMOS inverter pull-up transistor T4, and NMOS access transistor T6 all contribute to SEU sensitivity. The box method has been experimentally verified by vertical ion strike data on a 6T SRAM. The box method also predicts the SER due to an ion striking two different transistors and upsets due to body-tie strikes that can pull an output below ground or above the power supply rail.

It should be understood that the illustrated embodiments are examples only and should not be taken as limiting the scope of the present invention. The claims should not be read as limited to the described order or elements unless stated to that effect. Therefore, all embodiments that come within the scope and spirit of the following claims and equivalents thereto are claimed as the invention.

I claim:

1. A method for calculating a soft error rate, comprising in combination:
identifying at least one transistor in an integrated circuit cell that if impacted by an ion strike can cause an erroneous output of the integrated circuit cell;
identifying at least one portion of the at least one transistor that is sensitive to the ion strike; and
determining a critical charge and a dimension for the at least one portion.

2. The method of claim 1, wherein the at least one portion is represented by a box.

3. The method of claim 1, wherein the at least one portion is located in a region in which the ion strike causes parasitic bipolar action to occur.

4. The method of claim 3, wherein determining a critical charge for the at least one portion includes calculating an ion-induced drain current and using the calculation to simulate the critical charge.

5. The method of claim 4, wherein a circuit simulator is used to simulate the critical charge.

6. The method of claim 4, wherein determining the dimension for the at least one portion includes defining an x-dimension of a first box to contain positions in which the critical charge ranges from a minimum critical charge to two times the minimum critical charge.

7. The method of claim 6, further comprising characterizing the first box as having a charge equal to an average of the minimum critical charge and two times the minimum critical charge.

8. The method of claim 6, wherein determining the dimension for the at least one portion includes defining an x-dimension of additional boxes to contain positions in which the critical charge ranges from a factor of two from the critical charge range of the first box.

9. The method of claim 8, further comprising characterizing the additional boxes as having a charge equal to an average of the critical charge range.

10. The method of claim 1, wherein the at least one portion is located in a region in which the ion strike causes a drain of the at least one transistor to become forward biased.

11. The method of claim 10, wherein determining a critical charge for the at least one portion includes calculating a forward biased drain current that accounts for diode action and using the calculation to simulate the critical charge.

12. The method of claim 11, wherein a circuit simulator is used to simulate the critical charge.

13. The method of claim 11, wherein determining the dimension for the at least one portion includes defining an x-dimension of a box such that a value of the critical charge varies by a factor of two.

14. The method of claim 13, further comprising characterizing the at least one portion as having a charge of an average of the critical charge range of the box.

15. The method of claim 1, further comprising using the critical charge and the dimension to calculate a soft error rate for the integrated circuit cell.

16. The method of claim 15, wherein a partial soft error rate is determined for each of the portions of each of the transistors and the partial soft error rates are added to calculate the soft error rate for the integrated circuit cell.

17. The method of claim 15, wherein a partial soft error rate is determined for a dominant portion of each of the transistors and the partial soft error rates are added to calculate the soft error rate for the integrated circuit cell.

18. A method for calculating a soft error rate due to an ion that strikes two transistors to cause an upset, comprising in combination:
identifying two transistors in an integrated circuit cell that if both are impacted by an ion strike can cause an erroneous output of the integrated circuit cell;
modeling the two transistors as two boxes each having a dimension; and
calculating a soft error rate due to an ion striking the two boxes as a function of the box dimensions, distance from a center of the first box to the center of the second box, and an integral flux.

19. The method of claim 18, wherein the two transistors include a redundant transistor used to harden the integrated circuit cell.

20. The method of claim 18, wherein calculating the soft error rate includes using the formula:
SER=2F(Lₒ)w₁d₁w₂d₂/r²
where F(L) is the integral flux (in units of particles per μm²-steridian-day), Lₒ is the critical linear energy transfer (LET) required to cause an upset when both boxes are hit, r is the distance from the center of one box to the other, w is a width of the box, and d is a depth of the box.

21. The method of claim 18, further comprising transforming the two boxes if the boxes do not face each other.

22. A method for calculating a soft error rate to predict upset when an ion strike pulls a circuit node below ground or above a positive power supply, comprising in combination:
identifying at least one transistor in an integrated circuit cell that if impacted by an ion strike on a body tie region can cause a circuit node to be pulled below ground or above a positive power supply;
determining a critical charge for an portion of the transistor that includes at least part of a body and part of a drain of the transistor;
determining an x-dimension for the portion that contains positions in which the critical charge ranges from a minimum critical charge to two times the minimum critical charge;
characterizing the portion as having a charge equal to an average of the minimum critical charge and two times the minimum critical charge; and
using the critical charge and the dimension to predict a total soft error rate for the integrated circuit cell.
